(19) United States
(12) Patent Application Publication
(10) Pub. No.: US 2023/0092575 A1
(43) Pub. Date: Mar. 23, 2023

(54) FLEXIBLE TRANSPARENT ELECTRODE AND PREPARATION METHOD THEREFOR, AND FLEXIBLE SOLAR CELL PREPARED USING FLEXIBLE TRANSPARENT ELECTRODE

(71) Applicant: SOOCHOW UNIVERSITY, Suzhou (CN)

(72) Inventors: Yaowen LI, Suzhou (CN); Xiaobin CHEN, Suzhou (CN); Yongfang LI, Suzhou (CN)

(21) Appl. No.: 17/798,587

(22) PCT Filed: Feb. 10, 2020
(86) PCT No.: PCT/CN2020/074673

§ 371 Date: Aug. 10, 2022

(51) Int. Cl. H01L 51/44; H01L 51/00; H01L 51/42

(52) U.S. Cl. CPC H01L 51/441; H01L 51/0097; H01L 51/422

(57) ABSTRACT

A flexible solar cell is a flexible organic solar cell that can be completed at a low temperature, is easily prepared, and has a relatively low cost and relatively high efficiency. The flexible transparent electrode is prepared by selecting a plastic substrate with silver nanowires embedded therein, and thus, a flexible transparent electrode with better electrical properties, stronger adhesion and better mechanical properties can be obtained. The flexible transparent electrode prepared using the substrate with the silver nanowires embedded therein has lower sheet resistance and higher conductivity. Moreover, on a microstructure, the silver nanowires in the flexible substrate with the silver nanowires embedded therein can induce upper spin-coated silver nanowires to be more uniformly distributed, and can form nodes with the upper spin-coated silver nanowires, such that the adhesion between an upper electrode and the substrate is enhanced, which can further guarantee the good mechanical properties of the electrode.

### TECHNICAL FIELD

The invention relates to a flexible transparent electrode (FTE), specifically a new flexible transparent electrode and a flexible solar cell prepared using it therefor, and in particular, to a method of flexible transparent electrode base on PET of silver nanowire (AgNW) and the preparation of flexible organic solar cell.

### BACKGROUND TECHNIQUE

Flexible electronic devices, especially optoelectronic devices based on organic materials, are a major trend in the development of flexible electronic devices in the future and have huge application prospects. However, to obtain high-performance flexible transparent electrodes is a prerequisite for realizing high-efficiency flexible organic optoelectronic devices, and it is also a core problem in this field. How to obtain high conductivity, high light transmission, low surface roughness, simple preparation methods, and green flexible transparent electrode is still a huge challenge. Due to the lack of high-performance flexible transparent electrodes, the performance of flexible organic optoelectronic devices is still largely behind the corresponding rigid devices. Flexible transparent electrodes are usually prepared by dry methods (such as evaporation) or solution treatment processes. Compared with dry method preparation, solution processing method preparation has the advantages of low cost, large-scale printing preparation, etc., and has great development potential. The electrical and mechanical properties of flexible transparent electrodes play a vital role in the photoelectric conversion efficiency of solar cells. At present, PET plastic substrates are mainly used for the preparation of flexible transparent electrodes. The prepared flexible transparent electrodes have low adhesion to the substrate, and the electrical performance is poor; the existing methods for improving the electrical performance and adhesion of the flexible transparent electrode generally require a higher process and/or a higher energy consumption.

### Technical Problem

The present invention provides a novel flexible transparent electrode (FTE) preparation method, preferably a new flexible transparent electrode based on PET of silver nanowire (AgNW) by this welding strategy, critical bottleneck issues relating to the FTEs in terms of optoelectronic and mechanical properties are comprehensively addressed. The flexible organic solar cell based on this welded FTE show a high efficiency. There are no need high energy consumption of fabrication processes in whole electrode preparation, but have high repeatability and simple process.

### Technical Solutions

In order to achieve the above-mentioned object of the invention, the technical solution adopted by the present invention is: a flexible transparent electrode, the method of preparing the flexible transparent electrode comprises the following steps: Spin-coating the metal nanowires on the transparent plastic, and then coating curing resin to obtain a flexible transparent substrate; preparing conductive layer on the flexible transparent substrate to obtain the flexible transparent electrode.

A flexible solar cell includes flexible transparent electrode, active layer, hole transporting layer, and upper electrode layer; or includes flexible transparent electrode, active layer, electron transporting layer, and upper electrode layer; spin-coating metal nanowires onto the transparent plastic, and then coating curing resin to obtain the flexible transparent substrate; preparing the conductive layer on the flexible transparent substrate to obtain flexible transparent electrode.

The present invention discloses application in preparation of flexible devices with the flexible transparent electrode which the flexible devices include flexible solar cells and flexible sensors. The flexible transparent electrode is flexible solar cell electrode, coordinate with upper electrode in this invention.

The invention adopts a new flexible transparent electrode, which exhibits low sheet resistance (18 Ω/sq) and transmittance as high as 84%, realizing excellent intrinsic mechanical flexibility. Flexible solar cells that employ a plastic substrate and organic active layer provide ultrahigh optoelectronic property, the power conversion efficiencies can reach the level of rigid devices; the preparation of the active layer, the hole transporting layer or the electron transporting layer, and the upper electrode layer are the prior arts.

In the invention, preferably transparent plastics that the substrate materials of the flexible solar cells include PET, PEN, and so on; metal nanowire is silver nanowire (AgNW), AuNW. Particularly AgNWs with aspect ratios from 60:1 to 70:1; The curing resin is light curing resin, preferably UV-curing resin; the conductive layer composed of one or more of metal nanowires, conductive polymers, and metal oxides, preferably the conductive layer is a hybrid layer formed by AgNW and metal oxide. The metal oxide is preferably doped with metal oxide, such as aluminum doped metal oxide, and the metal nanowire is preferably AgNW.

The present invention spin-coating the metal nanowires solution onto the transparent plastic, and then coating curing resin to obtain a flexible transparent substrate, such as an embedded AgNW to the PET substrate (Em-Ag); As the substrate of flexible organic solar cell, has excellent transmittance the same with PET. That prepared conductive layer onto the flexible transparent substrate to obtain the electrode which is used to prepare flexible and transparent solar cells with excellent performance.

The present invention spin-coating the metal nanowires onto the flexible transparent substrate then coating metal oxide solution, after heating preparing conductive layer onto the flexible transparent substrate to obtain the flexible transparent electrode; or spin-coating conducting polymer solution onto the flexible transparent substrate, then coating metal oxide solution, after heating preparing conductive layer on the flexible transparent substrate to obtain the flexible transparent electrode; preferably, spin-coating the metal nanowires onto the flexible transparent substrate then coating metal oxide solution, after heating coating metal oxide solution again, and heating again preparing conductive layer onto the flexible transparent substrate to obtain the flexible transparent electrode; the flexible transparent electrode with thickness from 150 nm to 250 nm, the conductive layer with thickness from 10 nm to 100 nm. The thickness of flexible transparent electrode of the present invention is excluding the thickness of the transparent plastic, it is the thickness of the cured adhesive layer and the conductive layer. In the metal oxide solution, the concentration of metal oxide is ranging from 5 mg/mL to 20 mg/mL, preferably ranging from 5 mg/mL to 10 mg/mL; the temperature of heating is from 100° C. to 150° C., and heating time is from 10 to 30 min, preferably heating at 120° C. for 15 min; When spin-coating metal oxide solution, the rotation speed is from 1000 rpm to 3000 rpm, and the time is from 10 to 100 seconds, preferably when spin-coating metal oxide solution, the rotation speed is from 1500 rpm to 2500 rpm, and the time is from 40 to 60 seconds.

In the invention, in the metal nanowire solution, the solvent is water and/or alcohol solvent, preferably water; in the metal nanowire solution, the concentration of metal nanowire is ranging from 0.15 wt % to 0.5 wt %, preferably ranging from 0.22 wt % to 0.3 wt %; spin-coated metal In the case of nanowire solution, the rotation speed is from 1000 rpm to 3000 rpm and the time from 10 to 100 seconds, preferably when spin-coating metal oxide solution, the rotation speed is from 1500 rpm to 2500 rpm, and the time is from 40 to 60 seconds.

In the prior art, in order to obtain a thin film of uniformly distributed silver nanowire, a silver nanowire solution with concentration ranging from 0.15 wt % to 0.2 wt % is generally used for multiple spin coatings, and higher temperature annealing (>150° C.) is performed to obtain silver with lower sheet resistance. The nanowire film will cause certain damage to the PET plastic substrate; and the silver nanowire is spin-coated on a rigid substrate and then coated with a polymer, and then the film is uncovered to obtain a flexible electrode, which has good electrical properties and light transmittance. However, this method is not conducive to industrial production and is only suitable for small-scale laboratory research because of its choice of polymer precursors (requiring excellent film-forming properties) and rigid substrate surface properties (both metal nanowire bonding It also requires a certain degree of inertia.) The requirements are very high, which is easy to cause uneven film removal. In some places, it is easy to remove the film, and in some places, it is not easy to remove the film. Moreover, this method has very high requirements on the uniformity of spin coating, mainly because of its requirements. The binding force between silver nanowires and the polymer is much higher than the binding force between the polymer and the rigid substrate, and the polymer has no contact with the rigid substrate, which is beneficial to uncover the film. This is what industrial production cannot meet, and it also limits the industrial application of this method. In addition, although the performance of uncovering the film is better, it is not appropriate to directly use the uncovering film as an electrode to prepare a solar cell. The main reason is that the interface effect between the conductive layer and the active layer is not good. Compared with direct spin coating on polymer, the performance of the battery is reduced. Therefore, the prior art uses this as a conductive film, and there are almost no reports of using the film as a solar cell electrode; especially for the commonly used flexible substrate PET, due to its feature and cannot use this method. The present invention uses a PET plastic substrate embedded with silver nanowires as a substrate, preferably silver nanowire solution with 0.25 wt %, after low-speed spin coating (2000 rpm), combined with metal oxides, and then annealed at 120° C. to achieve high quality thin film (uniform distribution of silver nanowires on the surface, good stability, good repeatability, and flat film), while the sheet resistance is as low as 18 Ω/sq, and has excellent mechanical property, especially when combined with active layers. Excellent flexible solar cells have achieved unexpected technical effects.

In the invention, spin-coating the metal nanowire onto the transparent plastic, and then coating curing resin to obtain a flexible transparent substrate; preparing conductive layer on the flexible transparent substrate to obtain the flexible transparent electrode; spin-coating active layer material onto conductive layer of the flexible transparent electrode to obtain active layer; solvent evaporation and spin-coating hole transporting layer material on active layer to obtain hole transporting layer, preparing electrode via solvent evaporation and spin-coating on the hole transporting layer to obtain the flexible solar cell; or spin-coating electron transporting layer material on active layer to obtain electron transporting layer, preparing electrode via solvent evaporation and spin-coating on the electron transporting layer to obtain the flexible solar cell. The active layer, the hole transporting layer, the electron transporting layer, and the upper electrode layer are the prior materials; such as the active layer material is one or more of PBDB-T-2F, PTB7-Th, PCBM, IT-4F, and Y6; the electron transporting layer material is one or more of ZnO, TiO₂, SnO₂, PFN, PFN-Br, PDINO; the hole transporting layer material is one of poly[bis(4-phenyl)(2,4,6-trimethyl) Phenyl) amine], poly 3,4-ethylenedioxythiophene/polystyrene sulfonate, nickel oxide, copper oxide, 2,2′,7,7′-tetra[N,N-bis(4-methyl(oxyphenyl) amino]-9,9′-spirobifluorene, cuprous thiocyanate, molybdenum oxide, preparing the hole transporting layer via solvent evaporation and spin-coating on the active layer, the rotation speed is from 1000 rpm to 6000 rpm, and the time is from 20 s to 60 s, the hole transporting layer with thickness from 10 nm to 100 nm; the electron transporting layer material is one or more of ZnO, TiO₂, SnO₂, PFN, PFN-Br, PDINO, via the thermal annealing after spin-coating on active layer to obtain electron transporting layer, the rotation speed is from 2000 rpm to 5000 rpm, and the time is from 30 s to 60 s, the thermal annealing temperature is from 100° C. to 150° C. for 10 min to 60 min, the electron transporting layer with thickness from 10 nm to 100 nm; the electrode is one or more of Au electrode, Ag electrode, Al electrode, Cu electrode, PH1000 polymer electrode, and metal oxide electrode, via the thermal annealing and transfer on the hole transporting layer (the electron transporting layer) to obtain electrode; the electrode with thickness from 100 nm to 200 nm.

In the invention, the flexible transparent electrode is hybrid electrode, the structure is Em-Ag/AgNWs:AZO-SG, structure of each layer is a conventional after coating, no special structure preparation, for example, the prior art is not used the nanoimprint technology involved in the formation of special structures. The invention uses PET plastic substrate embedded with silver nanowires to prepare flexible transparent electrodes for the first time. The silver nanowires on the surface of the prepared flexible transparent electrodes are uniformly distributed, have good stability, good repeatability, and the film is flat; especially the flexible transparent electrodes prepared by the invention has low sheet resistance (18 Ω/sq) and excellent mechanical properties. After being prepared into a complete device, it exhibits extremely high photoelectric conversion efficiency. In the present invention, the flexible transparent electrode prepared by using the PET plastic substrate embedded with silver nanowires the conducting mechanism, morphology, electrical and optical properties, and mechanical stability were fully evaluated.

In the invention, due to the overall improvement in optoelectronic and mechanical properties, the flexible transparent electrode thus enhancing the adhesion of the electrode to the substrate, which is a promising candidate for using as the electrode in flexible OSCs, have simplify the process.

The insulated underlying PET substrate was also modified by embedding AgNWs in the UV-curing resin, thus enabling linkage between the AgNWs in the upper hybrid electrode and the underlying substrate. Through this approach, improvements were achieved not only with respect to the optoelectronic properties, such as conductivity and transmittance, but also in terms of the adhesion of the upper electrode to the substrate and the previously poor morphology of the upper hybrid electrode. The resultant welding AgNW-based FTE exhibits a low sheet resistance of 18 Ω/sq. To demonstrate its feasibility as an electrode for flexible solar cells, fullerene and nonfullerene active-layer materials with various bandgaps were explored. All the flexible solar cells displayed PCEs comparable to those of the corresponding rigid devices. Importantly, the PCEs of the flexible solar cells were less influenced by the device area and the devices display robust bending durability even under extreme test conditions.

### Beneficial Effect

1. In the present invention, a PET plastic substrate embedded with silver nanowires is selected to prepare a flexible transparent electrode, and the silver nanowires on the electrode surface are uniformly distributed, stable, and repeatable, the film is flat, and the prepared flexible organic solar cell has high photoelectric conversion efficiency; and high-quality flexible transparent electrodes also have good application prospects in the field of flexible electronic products;

2. The invention uses the PET plastic substrate embedded with silver nanowires instead of the traditional ordinary PET plastic substrate, and effectively improves the electrical and mechanical properties of the prepared flexible transparent electrode;

3. The flexible organic solar cell prepared by the present invention has the highest photoelectric conversion efficiency of the current single-junction organic flexible solar cell;

The above description is only an overview of the technical solution of the present invention. In order to understand the technical means of the present invention more clearly and implement it in accordance with the content of the description, the preferred embodiments of the present invention will be described in detail below with the accompanying drawings. The specific implementation of the present invention is given in detail by the following embodiments and the accompanying drawings.

### DESCRIPTION OF THE DRAWINGS

FIG. 1 is a schematic diagram of flexible transparent electrode fabrication process is presented in Example 1;

FIG. 2 shows SEM images of flexible transparent electrodes prepared with PET plastic substrate embedding AgNWs and normal PET plastic substrate in Example 1;

FIG. 3 shows SEM images of cross-sectional of flexible transparent electrodes prepared with PET plastic substrate embedding AgNWs and normal PET plastic substrate in Example 1;

FIG. 4 shows the adhesive force values of flexible transparent electrodes prepared with PET plastic substrate embedding AgNWs and normal PET plastic substrate in Example 1, inset: schematic illustration of adhesive force measurements;

FIG. 5 shows sheet resistance change of the FTEs prepared with PET plastic substrate embedding AgNWs and normal PET plastic substrate in Example 1 with increasing bending cycles for inward and outward bending tests (with a 4 mm bending radius);

FIG. 6 shows the photograph of Em-Ag/AgNWs:AZO-SG FTE in Example 1;

FIG. 7 shows schematic illustration of a flexible solar cells and molecular structures in Example 2;

FIG. 8 shows J-V curves under the illumination of flexible solar cells prepared with PET plastic substrate embedding AgNWs and normal PET plastic substrate in Example 2;

FIG. 9 shows flexible solar cells prepared with PET plastic substrate embedding AgNWs and normal PET plastic substrate in Example 2 versus bending cycles at a radius of 4 mm;

FIG. 10 shows J-V curves under the illumination of flexible solar cells prepared with PET plastic substrate embedding AgNWs and Em-Ag/AgNWs:AZO-SG in Example 3.

### DETAILED DESCRIPTION

The flexible transparent electrode of the present invention adopts a hybrid electrode structure to combine silver nanowires with metal oxides or conductive polymers, solving the problem of low coverage of silver nanowires, and avoiding excessively high contact resistance between silver nanowires and low device efficiency. All the raw materials of the present invention are commercially available and meet the application requirements of flexible solar cells. For example, the ultraviolet curing adhesive is a conventional transparent ultraviolet curing adhesive, which is a commercially available product, such as Organtecsolar Materials Inc. The test method involved in the embodiment of the present invention is a flexible solar cell routine testing methods.

In the following, the present invention will be described in detail in conjunction with embodiments:

### Example 1

(1) On the surface of the PET plastic substrate (pure PET, untreated, non-conductive) spin-coated silver nanowires (length 2 um, diameter 30 nm) aqueous solution (0.25 wt %) at 2000 rpm for 40 s without heating, and then on the AgNWs scraped a layer of UV-curing resin at 20 mm/s speed, 80 nm height, then used UV lamp (distance with lamp was 18 cm, energy of UV was 335 mJ/cm) to cure for 1 min to form a PET plastic substrate embedded with silver nanowires (Em-Ag), as the substrate of flexible organic solar cells, the transmittance was similar to that of pure PET, but with a high resistance (130 Ω/sq) and cannot be directly used as a flexible electrode;

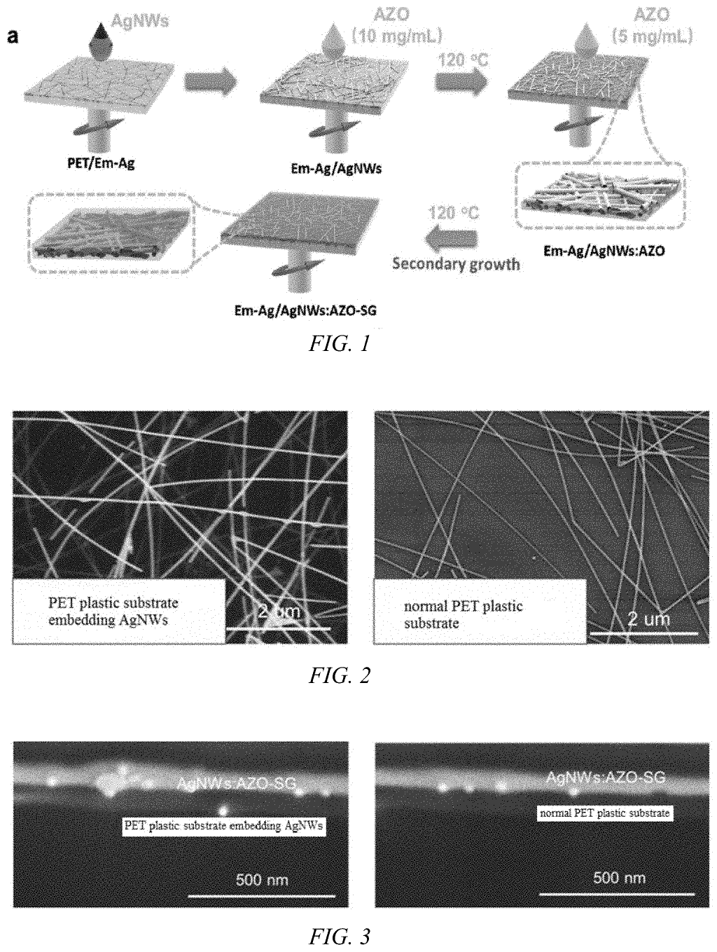

(2) Spin-coated AgNWs solution (0.25 wt %) onto the Em-Ag substrate at 2000 rpm for 40 s, without heating, and then 10-mg/mL-Al-doped ZnO (AZO) solution was spin-coated onto the obtained AgNWs film, at 2000 rpm for 1 min, followed by a thermal annealing process in air at 120° C. for 15 min, then 5-mg/mL-AZO solution was spin-coated onto the AgNWs:AZO film at 2000 rpm for 1 min, which also followed by a thermal annealing process in air at 120° C. for 15 min, with total thickness of ≈180 nm. So far, the preparation of flexible transparent electrode was completed. The thickness of the UV-curing resin layer was 80 nm and the thickness of the conductive layer was 100 nm; FIG. 1 was a schematic diagram of flexible transparent electrode fabrication process was presented, the thickness of PET plastic substrate was not included in flexible transparent electrode, flexible transparent electrode is Em-Ag/AgNWs:AZO-SG.

Replace the PET plastic substrate embedded with silver nanowires (Em-Ag) in the above step (2) with the normal PET plastic substrate (pure PET, untreated), and the rest remain unchanged to obtain a flexible transparent electrode prepared by normal PET plastic, as a comparison.

FIG. 2 shows SEM images of flexible transparent electrodes prepared with PET plastic substrate embedding AgNWs and normal PET plastic substrate. It can be clearly seen that the presence of this worm-like AZO film throughout the AgNW network (AgNWs:AZO) is more uniform.

FIG. 3 shows SEM images of cross-sectional of flexible transparent electrodes prepared with PET plastic substrate embedding AgNWs and normal PET plastic substrate (pure PET, untreated).

It can be clearly seen that the flexible transparent electrode of AgNWs:AZO, junction site in the upper and the underlying AgNWs substrate enhancing the adhesion of the electrode to the substrate.

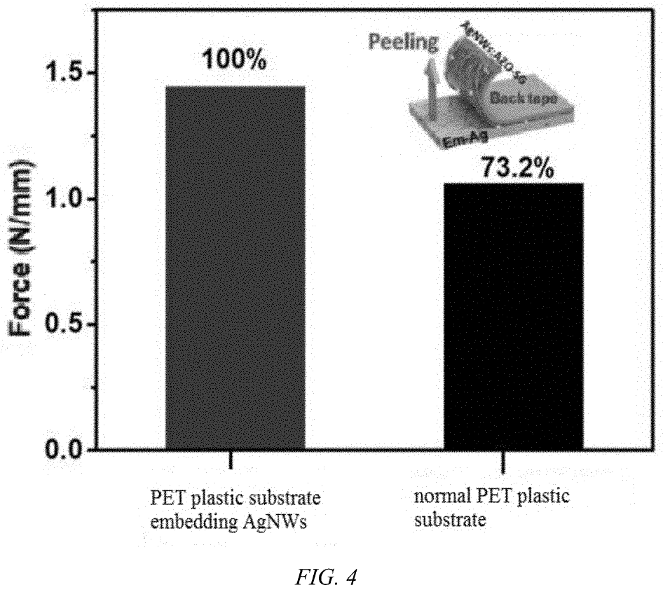

FIG. 4 shows the adhesive force values of flexible transparent electrodes prepared with PET plastic substrate embedding AgNWs and normal PET plastic substrate (pure PET, untreated), by 90° peel measurements, the adhesion of the PET plastic substrate embedding AgNWs and normal PET plastic substrate FTEs of 72.3% relative to that of the Em-Ag/AgNWs:AZO-SG FTE. It can enhance the adhesion of the electrode to the substrate. The thickness of the UV-curing resin layer was adjusted to 50 nanometers, and the rest was the same as the above, the flexible transparent electrode was prepared, and the adhesion was tested by the same method, which was 1.18 times higher compared to that of the flexible transparent electrode prepared from the normal PET plastic substrate.

The concentration of the silver nanowire aqueous solution was adjusted to 0.3 wt %, and the rest was the same as the above, the flexible transparent electrode was prepared, and the adhesion was tested by the same method, which was 1.34 times higher compared to that of the flexible transparent electrode prepared on the normal PET plastic substrate. The spin-coated speed was adjusted to 2000 rpm/50 s, and the rest was the same as the above, the flexible transparent electrode was prepared, and the adhesion was tested by the same method, which was 1.35 times that of the flexible transparent electrode prepared on the normal PET plastic substrate.

The sheet resistance of the Em-Ag/AgNWs:AZO-SG FTE calculated from the statistical results was 18 Ω/sq (measured with a four-probe instrument), which is comparable to that of the conventional and much lower than those of the FTEs (30 Ω/sq) prepared on the normal PET plastic substrate. This result is also consistent with their respective conductivity values, the Em-Ag/AgNWs:AZO-SG FTEs can improve the electrical performance of the electrode.

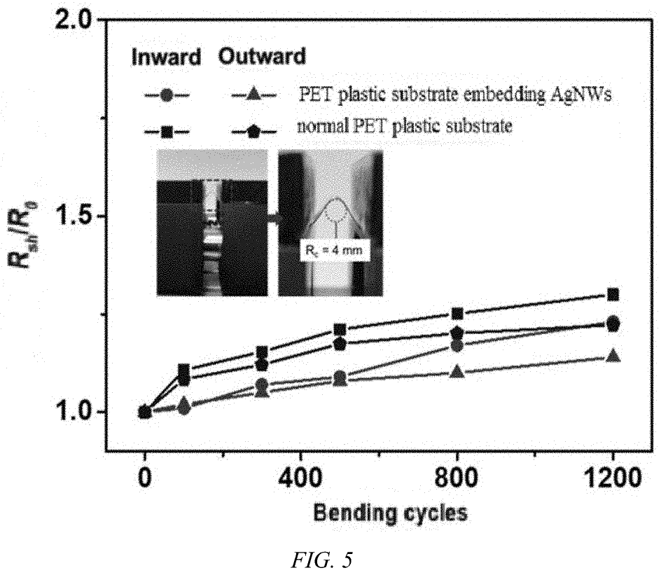

FIG. 5 shows sheet resistance change of the FTEs prepared with PET plastic substrate embedding AgNWs and normal PET plastic substrate (pure PET, untreated) with increasing bending cycles for inward and outward bending tests. The bending durability of the FTEs in the inward or outward direction was evaluated via the ratio of the sheet resistance to the initial resistance with the evolution of bending cycles at a bending radius of 4 mm. As shown in FIG. 5, the Rsh/R0 of the AgNWs:AZO-SG grown on the bare PET substrate was slightly increased after 1200 bending cycles in the inward direction, indicating that the increase in adhesion was conducive to improving the mechanical properties of the electrode.

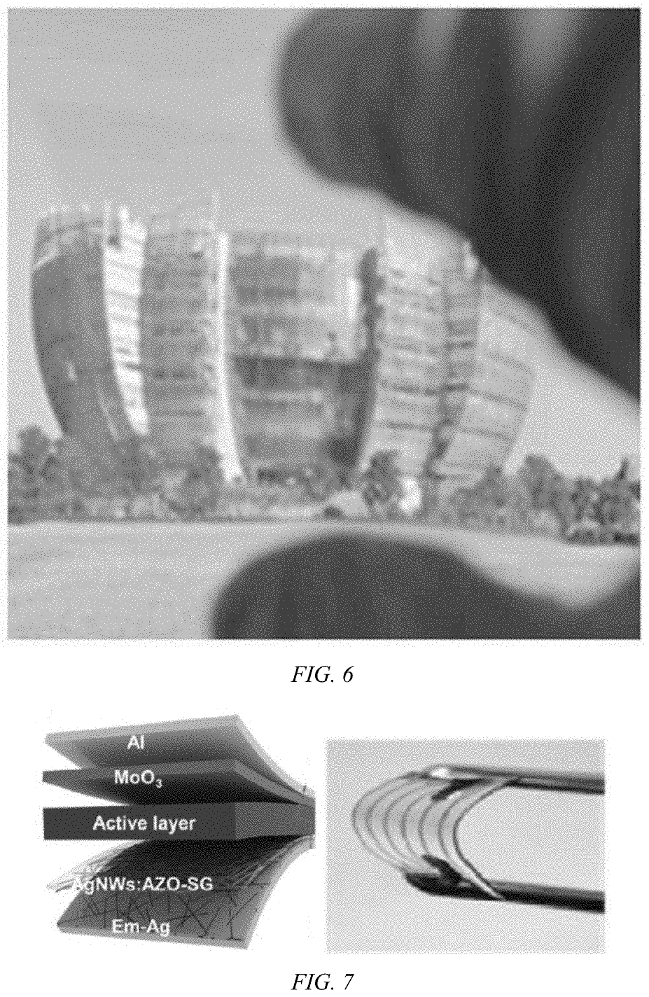

FIG. 6 shows the photograph of Em-Ag/AgNWs:AZO-SG FTE, the electrode in the present has a high transmittance of 84% in common text, and transmittance of the pure PET plastic substrate is 89%.

### Control Example

On the surface of the PET plastic substrate (pure PET, untreated, consistent with Example 1) scraped a layer of UV-curing resin, after dried, spin-coated AgNWs solution (0.25 wt %) at 2000 rpm for 40 s without heating, then used UV lamp (distance with lamp is 18 cm, energy of UV is 335 mJ/cm) to cure for 1 min to form a PET plastic substrate embedded with silver nanowires, as the substrate of flexible organic solar cells; Spin-coated AgNWs solution (0.25 wt %) onto the substrate at 2000 rpm for 40 s, without heating, and then 10-mg/mL-Al-doped ZnO (AZO) solution was spin-coated onto the obtained AgNWs film, at 2000 rpm for 1 min, followed by a thermal annealing process in air at 120° C. for 15 min, then 5-mg/mL-AZO solution was spin-coated onto the AgNWs:AZO film at 2000 rpm for 1 min, which also followed by a thermal annealing process in air at 120° C. for 15 min, to prepare the flexible transparent electrode. The thickness of the UV-curing resin layer was 80 nm and the thickness of the conductive layer was 100 nm. At the same test, the sheet resistance was 28 Ω/sq, at a bending radius of 4 mm after 1200 bending cycles in the inward direction, the sheet resistance was 1.3 times that was similar to pure PET.

On the surface of the PET plastic substrate (pure PET, untreated, consistent with Example 1) spin-coated AgNWs solution (0.25 wt %) at 2000 rpm for 40 s without heating, and then spin-coated AgNWs solution (0.25 wt %) onto the substrate at 2000 rpm for 40 s again, without heating, and then 10-mg/mL-Al-doped ZnO (AZO) solution was spin-coated onto the obtained AgNWs film, at 2000 rpm for 1 min, followed by a thermal annealing process in air at 120° C. for 15 min, then 5-mg/mL-AZO solution was spin-coated onto the AgNWs:AZO film at 2000 rpm for 1 min, which also followed by a thermal annealing process in air at 120° C. for 15 min, to prepare the flexible transparent electrode. The thickness of the UV-curing resin layer was 80 nm and the thickness of the conductive layer was 100 nm. At the same test, the sheet resistance was 24 Ω/sq, at a bending radius of 4 mm after 1200 bending cycles in the inward direction, the sheet resistance was 1.4 times that was worse than the pure PET.

On the surface of the Em-Ag spin-coated conductive polymer PH1000 at 1400 rpm for 60 s, followed by a thermal annealing process at 100° C. for 15 min, and then spin-coated PETE at 5000 rpm/30 s to obtain a flexible transparent electrode; At the same test, the sheet resistance was 90 Ω/sq, the transmittance was only 75%, worse than the AgNWs:AZO hybrid layer.

### Example 2

The flexible transparent electrode prepared in Example 1 is placed in a nitrogen glove box, and spin-coated the active layer solution onto the surface of the conductive layer. The components of the solution were PBDB-T-2F, Y6, the solvent was pure CF, and the concentration was 16 mg/mL of solution, the spin-coating rate was 3000 rpm for 30 s, after dripping, by a thermal annealing process at 110° C. for 10 min, to prepare the active layer; In the coating machine, the MoO₃ hole transporting layer is vapor-deposited on the surface of the active layer and Al electrode, the thickness is 10 nm and 100 nm, respectively. So far, the preparation of the flexible solar cell is completed. It is a flexible organic solar cell prepared with a PET plastic substrate embedded with silver nanowires. The schematic illustration is shown in FIG. 7.

The flexible transparent electrode prepared on the normal PET plastic substrate in Example 1 was placed in a nitrogen glove box, and the same preparation steps were performed to obtain a flexible organic solar cell by the normal PET plastic substrate, in comparison.

The PET plastic substrate of Example 1 was replaced with a PEN plastic substrate, and the same preparation steps were performed to obtain a flexible organic solar cell prepared from a PEN plastic substrate embedded with silver nanowires, with the efficiency (PCE) of 14.93%.

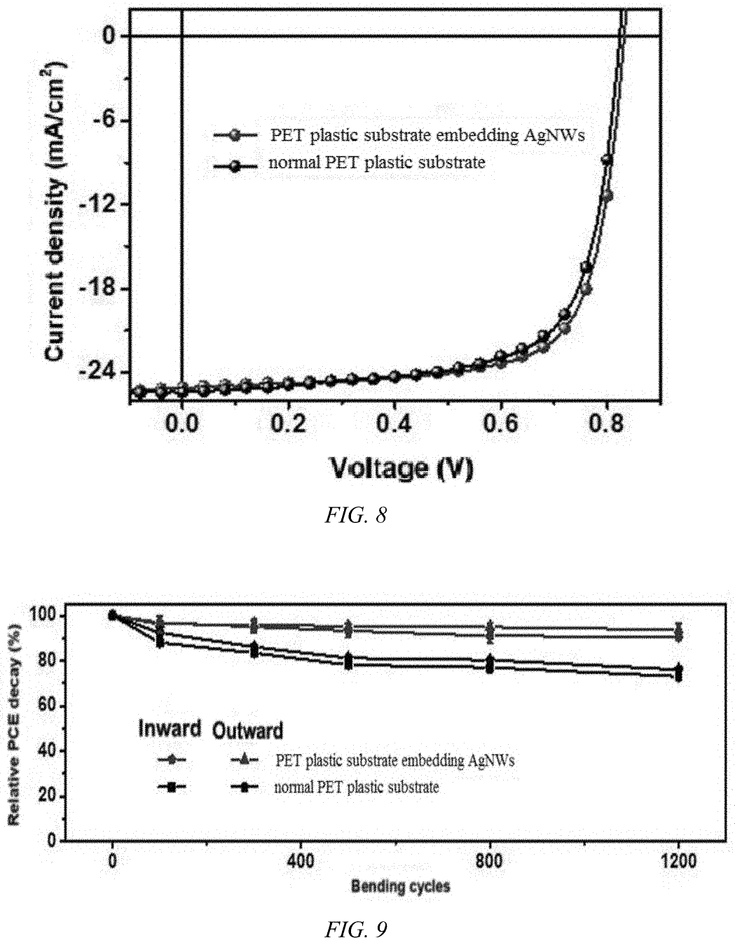

Table 1 and FIG. 8 are the photovoltaic performance parameters and J-V curves under the illumination of flexible solar cells prepared with PET plastic substrate embedding AgNWs and normal PET plastic substrate.

It can be seen that the performance of flexible organic solar cells made of normal PET plastic substrates has declined, and the battery repeatability is not good. The efficiency of flexible organic solar cells made of PET plastic substrates embedded with silver nanowires is 15.21%, which is also the highest reported efficiency of single-junction flexible organic solar cells is close to (15.78%) of organic solar cells with rigid substrates (the substrate is glass, the electrodes are indium tin oxide, and the rest are the same).

TABLE 1
Photovoltaic performance parameters of PET plastic
substrate embedding AgNWs and normal PET plastic substrate

| | V_{OC} | J_{SC} | FF | PCE |
|---|---|---|---|---|
| Electrode | (V) | (mA/cm²) | (%) | (%) |
| PET plastic substrate | 0.832 | 25.05 | 72.97 | 15.21 |
| embedding AgNWs | | | | |
| normal PET plastic substrate | 0.824 | 25.43 | 69.77 | 14.61 |

FIG. 9 shows flexible solar cells prepared with PET plastic substrate embedding AgNWs and normal PET plastic substrate versus bending cycles at a radius of 4 mm (the upper electrode as the inside);

It can be seen that the various properties of flexible organic solar cell prepared with a normal plastic substrate drop sharply. At a bending, the sheet resistance was 1.3 times that was similar to pure PET, the flexible OSCs based on Em-Ag/AgNWs:AZO-SG FTEs maintained 93% of its initial value when radius of 4 mm after 1200 bending cycles in the inward direction, demonstrating the well-maintained photovoltaic parameters. It was successfully developed in order to overcome the shortcomings of poor bending performance of batteries prepared in the prior arts, and achieves unexpected technology.

### Example 3

On the surface of the Em-Ag spin-coated conductive polymer PH1000, then spin-coated PETE, and then spin-coated 5-mg/mL-AZO solution followed by a thermal annealing process at 120° C. for 15 min, at 2000 rpm/60 s to obtain a flexible transparent electrode was placed in a nitrogen glove box, and then the same battery preparation steps as in Example 2 were performed to obtain flexible organic solar cells.

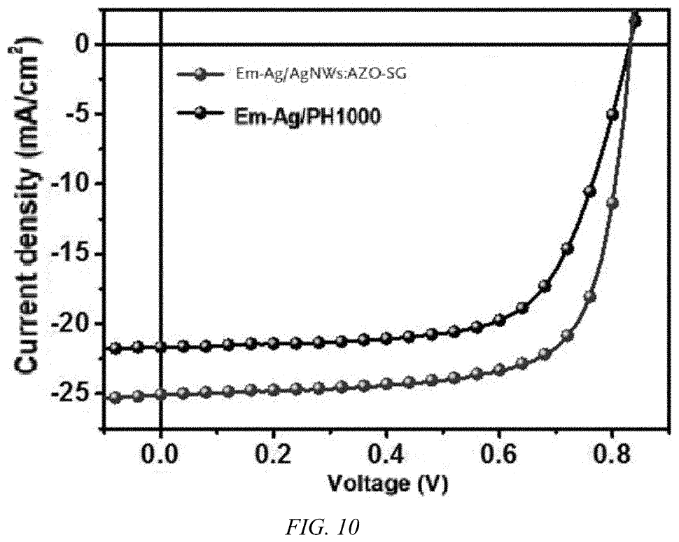

Table 2 and FIG. 10 are the photovoltaic performance parameters and J-V curves of Em-Ag/AgNWs:AZO-SG in Example 2 and Em-Ag/PH1000 in Example 3.

The results indicate that the FTE design with an integrated underlying substrate and upper electrode layer effectively enhanced the optoelectronic and mechanical properties of the flexible OSCs.

TABLE 2
Photovoltaic performance parameters of Em-Ag/AgNWs:AZO-SG
in Example 2 and Em-Ag/PH1000 in Example 3

| | V_{OC} | J_{SC} | FF | PCE |
|---|---|---|---|---|
| Electrode | (V) | (mA/cm²) | (%) | (%) |
| Em-Ag/AgNWs:AZO-SG | 0.832 | 25.05 | 72.97 | 15.21 |
| Em-Ag/PH1000 | 0.826 | 21.90 | 67.38 | 12.19 |

1. A flexible transparent electrode, characterized in that a method of preparing the flexible transparent electrode comprises the following steps: spin-coating a metal nanowire on a transparent plastic, and then coating with a curing resin to obtain a flexible transparent substrate; preparing a conductive layer on the flexible transparent substrate to obtain the flexible transparent electrode.

2. The flexible transparent electrode of claim 1, characterized in that, the curing resin is a light curing resin; the conductive layer is one or more selected from the group consisting of the metal nanowire, a conductive polymer, and a metal oxide.

3. The flexible transparent electrode of claim 1, characterized in that, spin-coating the metal nanowire onto the transparent plastic, and then coating with the curing resin to obtain the flexible transparent substrate; spin-coating the metal nanowire onto the flexible transparent substrate and then coating with a metal oxide solution, heating and preparing the conductive layer onto the flexible transparent substrate to obtain the flexible transparent electrode; or spin-coating a conducting polymer solution onto the flexible transparent substrate, then coating with the metal oxide solution, heating and preparing the conductive layer on the flexible transparent substrate to obtain the flexible transparent electrode.

4. The flexible transparent electrode of claim 3, characterized in that, in the metal oxide solution, a metal oxide concentration is ranging from 5 mg/mL to 20 mg/mL; a heating temperature is from 100° C. to 150° C., and a heating time is from 10 to 30 min; when spin-coating with the metal oxide solution, a rotation speed is from 1000 rpm to 3000 rpm, and a coating time is from 10 to 100 seconds; in the metal nanowire solution, a metal nanowire concentration is ranging from 0.15 wt % to 0.5 wt %; when spin-coating with the metal nanowire solution, a rotation speed is from 1000 rpm to 3000 rpm, and a coating time is from 10 to 100 seconds.

5. A flexible solar cell, comprising a flexible transparent electrode, an active layer, a hole transporting layer, and an upper electrode layer; or comprising a flexible transparent electrode, an active layer, an electron transporting layer, and an upper electrode layer; spin-coating a metal nanowire onto the transparent plastic, and then coating with a curing resin to obtain the flexible transparent substrate; preparing the conductive layer on the flexible transparent substrate to obtain flexible transparent electrode.

6. The flexible solar cell of claim 5, characterized in that the active layer material is one or more selected from the group consisting of PBDB-T-2F, PTB7-Th, PCBM, IT-4F, and Y6; the electron transporting layer material is one or more selected from the group consisting of ZnO, TiO₂, SnO₂, PFN, PFN-Br, PDINO; the hole transporting layer material is one or more selected from group consisting of poly[bis(4-phenyl)(2,4,6-trimethyl) Phenyl) amine], poly 3,4-ethylenedioxythiophene/polystyrene sulfonate, nickel oxide, copper oxide, 2,2′,7,7′-tetra[N,N-bis(4-methyl(oxyphenyl)amino]-9,9′-spirobifluorene, cuprous thiocyanate, molybdenum oxide; the electrode is one or more selected from the group consisting of an Au electrode, an Ag electrode, an Al electrode, a Cu electrode, a PH1000 polymer electrode, and a metal oxide electrode.

7. The flexible solar cell of claim 5, characterized in that the curing resin is a light curing resin; the conductive layer is one or more selected from the group consisting of a metal nanowire, a conductive polymer, and a metal oxide; spin-coating the metal nanowire onto the transparent plastic, and then coating with the curing resin to obtain a flexible transparent substrate; spin-coating the metal nanowire onto the flexible transparent substrate then coating with the metal oxide solution, heating and preparing conductive layer onto the flexible transparent substrate to obtain the flexible transparent electrode; or spin-coating with the conducting polymer solution onto the flexible transparent substrate, then coating with the metal oxide solution, heating and preparing conductive layer on the flexible transparent substrate to obtain the flexible transparent electrode.

8. The flexible solar cell of claim 7, characterized in that in metal oxide solution, a metal oxide concentration is ranging from 5 mg/mL to 20 mg/mL; a heating temperature is from 100° C. to 150° C., and a heating time is from 10 to 30 min; when spin-coating with the metal oxide solution, a rotation speed is from 1000 rpm to 3000 rpm, and a coating time is from 10 to 100 seconds; in the metal nanowire solution, a metal nanowire concentration is ranging from 0.15 wt % to 0.5 wt %; when spin-coating with the metal nanowire solution, a rotation speed is from 1000 rpm to 3000 rpm, and a coating time is from 10 to 100 seconds.

9. An Application in preparation of a flexible device with the flexible transparent electrode in claim 1.

10. The application of claim 9, characterized in that the flexible device includes flexible solar cells and flexible sensors.
